(19) United States
(12) Patent Application Publication
(10) Pub. No.: US 2016/0190367 A1
(43) Pub. Date: Jun. 30, 2016

(54) PACKAGING STRUCTURE OF COLOR TUNABLE SOLAR CELL

(71) Applicant: HYUNDAI MOTOR COMPANY, Seoul (KR)

(72) Inventors: Sol KIM, Seoul (KR); Moon Jung EO, Seoul (KR); Sang Hak KIM, Seoul (KR); Won Jung KIM, Seoul (KR)

(21) Appl. No.: 14/928,902

(22) Filed: Oct. 30, 2015

(30) Foreign Application Priority Data
Dec. 30, 2014 (KR) 10-2014-0194123

(51) Int. Cl. H01L 31/048; H01L 31/0216; H01G 9/20

(52) U.S. Cl. CPC H01L 31/048; H01G 9/209; H01G 9/2077; H01L 31/02167

(57) ABSTRACT

A packaging structure of a solar cell includes a first substrate and a first laminating film attached to a back surface of the first substrate. The solar cell, which includes one or more substrates, is attached to a back surface of the first laminating film. A second laminating film is attached to a back surface of the solar cell, and a second substrate is attached to a back surface of the second laminating film. The solar cell includes a light absorption unit color-tuned and a pattern unit with which second substrate is pattern matched. The second substrate is tuned with the same color as the light absorption unit.

### CROSS-REFERENCE TO RELATED APPLICATION

This application claims under 35 U.S.C. §119(a) the benefit of priority to Korean Patent Application No. 10-201 4-0194123 filed on Dec. 30, 2014, the entire content of which is incorporated herein by reference.

### TECHNICAL FIELD

The present disclosure relates to a color tunable solar cell. More particularly, the present disclosure relates to a color tunable solar cell capable of enhancing esthetic impression while preventing a moire pattern in the solar cell and mitigating dizziness due to a color difference and improving visual fatigue.

### BACKGROUND

A semi-transparent solar cell, such as a dye-sensitized solar cell, organic solar cells, and a thin film amorphous solar cell, has been developed for the use in fittings, glass, windows, and the like due to unique characteristics caused by its semi-transparency.

However, the semi-transparent solar cell uses a collector electrode or a laser scribing line in order to decrease resistance in a large-area module and thus disturbs a user's view. Further a moire effect and the like occur due to repetition of the same pattern which increases visual fatigue. Particularly, when the semi-transparent solar cell is used on a window of a vehicle, a train, and the like, dizziness may occur due to interference between moving forms and fixed repetitive patterns.

As an existing technology, there is a dye-sensitized solar cell including two glass sheets coated with transparent conductive layers, a photoelectrode, an electrolyte, a counter electrode, and a light reflective paint film obtained by painting light reflective coating on an external surface of the photoelectrode, however, dizziness may still occur due to a pattern of a collector electrode unit of the solar cell.

In another related art, a dye-sensitized solar cell includes two substrates spaced apart at opposite sides to each other, and an electrolyte between the upper substrate and the lower substrate. On an external surface of any one of the substrates, a first coating layer includes a curable material thereon, and a paint layer is applied on the first coating layer are included. However, the solar cell having such a constitution may have a moire pattern and the like due to a laser line.

Accordingly, the development of a solar cell capable of preventing esthetic impression decline or dizziness caused by a repetitive pattern of a collector electrode, a scribing line, or the like of the solar cell is required.

The above information disclosed in this Background section is only for enhancement of understanding of the background of the invention, and therefore, it may contain information that does not form the prior art that is already known in this country to a person of ordinary skill in the art.

### SUMMARY OF THE DISCLOSURE

The present disclosure has been made in an effort to solve the above-described problems associated with prior art, by using a substrate tuned with the same color as a light absorption unit of a solar cell to pattern match with a pattern unit of the solar cell, thus enhancing esthetic impression while preventing a moire effect caused due to repetition of the light absorption unit and the pattern unit in the solar cell reducing dizziness induced by a color difference.

An aspect of the present inventive concept provides a packaging structure of a solar cell capable of mitigating dizziness induced by a color difference.

Another aspect of the present inventive concept provides a packaging structure of a solar cell capable of preventing esthetic impression decline and a moire effect, and in which overall color tuning of the solar cell is simple.

According to an exemplary embodiment of the present inventive concept, a packaging structure of a solar cell comprises a first substrate and a first laminating film attached to a back surface of the first substrate. The solar cell, which includes one or two substrates, is attached to a back surface of the first laminating film and includes a light absorption unit and a pattern unit. A second laminating film is attached to a back surface of the solar cell, and a second substrate is attached to a back surface of the second laminating film. The light absorption unit is color-tuned, and the second substrate is tuned with the same color as the light absorption unit while pattern matched with the pattern unit.

Other aspects and exemplary embodiments of the invention are discussed infra.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

### BRIEF DESCRIPTION OF THE DRAWINGS

The above and other features of the present disclosure will now be described in detail with reference to certain exemplary embodiments thereof illustrated the accompanying drawings which are given hereinbelow by way of illustration only, and thus are not limitative of the present disclosure.

FIG. 1 is a diagram showing a packaging structure of a solar cell according to the present disclosure.

FIG. 2 is a diagram showing a second substrate pattern matched with a pattern unit of a solar cell according to the present disclosure.

FIG. 3A is a picture showing a front surface of an amorphous solar cell having scribing lines.

FIG. 3B illustrates shining a user's hand to an amorphous solar cell as a comparative example according to the present disclosure.

FIG. 4 is a cross-sectional diagram of the amorphous solar cell of Example 1 according to the present disclosure.

FIG. 5 is a picture showing a front surface of the amorphous solar cell of Example 1 according to the present disclosure before and after pattern matching a scribing line with a second substrate.

FIG. 6 is a cross-sectional diagram of an amorphous solar cell of Example 2 according to the present disclosure.

FIG. 7 is a picture showing a front surface of the amorphous solar cell of Example 2 according to the present disclosure before and after pattern matching a scribing line with a second substrate while a color laminating film is attached.

It should be understood that the appended drawings are not necessarily to scale, presenting a somewhat simplified representation of various features illustrative of the basic principles of the invention. The specific design features of the present invention as disclosed herein, including, for example, specific dimensions, orientations, locations, and shapes will be determined in part by the particular intended application and use environment.

In the figures, reference numbers refer to the same or equivalent parts of the present invention throughout the several figures of the drawing.

### DETAILED DESCRIPTION

Hereinafter reference will now be made in detail to various embodiments of the present inventive concept, examples of which are illustrated in the accompanying drawings and described below. While the invention will be described in conjunction with exemplary embodiments, it will be understood that present description is not intended to limit the invention to those exemplary embodiments. On the contrary, the invention is intended to cover not only the exemplary embodiments, but also various alternatives, modifications, equivalents, and other embodiments, which may be included within the spirit and scope of the invention as defined by the appended claims.

Hereinafter, the present disclosure will be described in more detail with an example.

A solar cell according to the present disclosure includes a first substrate and a first laminating film attached to a back surface of the first substrate. The solar cell has one or more substrates attached to a back surface of the first laminating film and includes a light absorption unit and a pattern unit thereon. A second laminating film is attached to a back surface of the solar cell. A second substrate is attached to a back surface of the second laminating film. The light absorption unit of the solar cell is color-tuned, and the second substrate may be tuned with the same color as the light absorption unit while pattern matching with the pattern unit.

According to the present disclosure, by pattern matching the pattern unit with the second substrate and tuning the substrate with the same color as the light absorption unit, the solar cell prevents esthetic impression decline caused by repetition of the light absorption unit and the pattern unit in a semi-transparent solar cell, prevents dizziness caused by a color difference, prevents a moire phenomenon, and the like, and corrects the overall color tone of the solar cell.

FIG. 1 is a diagram showing a packaging structure of a solar cell according to the present disclosure. In the solar cell packaging structure according to the present disclosure, a first laminating film 2 is attached to a back surface of the first substrate 1, and the solar cell 3 is attached to a back surface of the first laminating film 2. A second laminating film 4 is attached to a back surface of the solar cell 3, and a second substrate 5 is attached to a back surface of the second laminating film 4.

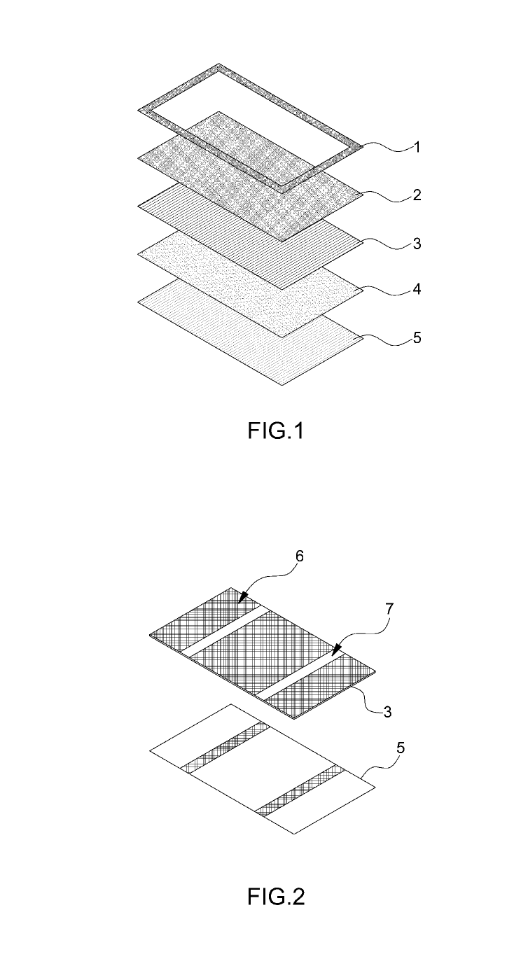

FIG. 2 is a diagram showing a second substrate pattern matched with a pattern unit a solar cell according to the present disclosure. Referring to FIG. 2, the solar cell 3 includes a light absorption unit 6 and a pattern unit 7 in which the color is tuned in the light absorption unit 6. The second substrate 5 is pattern matched with the pattern unit 7 and has the same color as the light absorption unit 6. The second substrate 5 has the same pattern as the pattern unit 7 of the solar cell 3, thus reducing a color difference by having the same RGB values as the light absorption unit 6. Herein, the pattern may be formed using a method such as color deposition or printing.

According to the present disclosure, the first and the second substrates 1, 5 may include glass, a transparent plastic, or polymer film. The first and the second substrates 1, 5 may include materials that are the same as or different from each other, or may use a transparent substrate to allow light passes through the cell of the solar cell 3.

According to the present disclosure, the first and the second laminating films 2, 4 may use polyvinyl butyral (PVB), ethylene vinyl acetate (EVA), or a mixture of these two. The first and the second laminating films 2, 4 may use the same or different materials from each other. In addition, the first and the second laminating films 2, 4 securely attach the first and the second substrates 1, 5 and the cell of the solar cell 3, and have excellent adhesive strength with glass, high light transmittance, and block ultraviolet light.

According to the present disclosure, the second laminating film 4 may be a color laminating film which is a front surface color laminating film colored between the solar cell and the second substrate. The front surface color laminating film reduces visual fatigue of the solar cell and enhances cell efficiency by introducing a target color.

According to the present disclosure, in the color laminating film, the target color is added to polyvinyl butyral (PVB), ethylene vinyl acetate (EVA), or a mixture of these two that is the same as the first and the second laminating films 2, 4.

According to the present disclosure, the light absorption unit 6 is an active layer or a photoelectrode, and the pattern unit 7 may be a scribing line or a collector electrode.

According to the present disclosure, the solar cell 3 may be an amorphous solar cell or a dye-sensitized solar cell. The amorphous solar cell has one substrate, and may include an active layer that is a light absorption unit and a scribing line that is a pattern unit. The dye-sensitized solar cell has two substrates, and may include a photoelectrode that is a light absorption unit and a collector electrode that is a pattern unit.

Accordingly, the solar cell according to the present disclosure can enhance esthetic effect while preventing a moire pattern due to repetition of a light absorption unit and a pattern unit in a solar cell and reduce user's dizziness due to a color difference by using a substrate having the same color as the light absorption unit of the solar cell while pattern matched with a pattern unit the solar cell. In addition, the solar cell according to the present disclosure can improve user's visual fatigue by correcting the overall color tone of the solar cell using a color laminating film, which is color tuned, between t the solar cell and the substrate.

### EXAMPLES

Hereinafter, the present disclosure will be described in more detail with reference to the attached drawings, however, the present disclosure is not limited to the attached drawings.

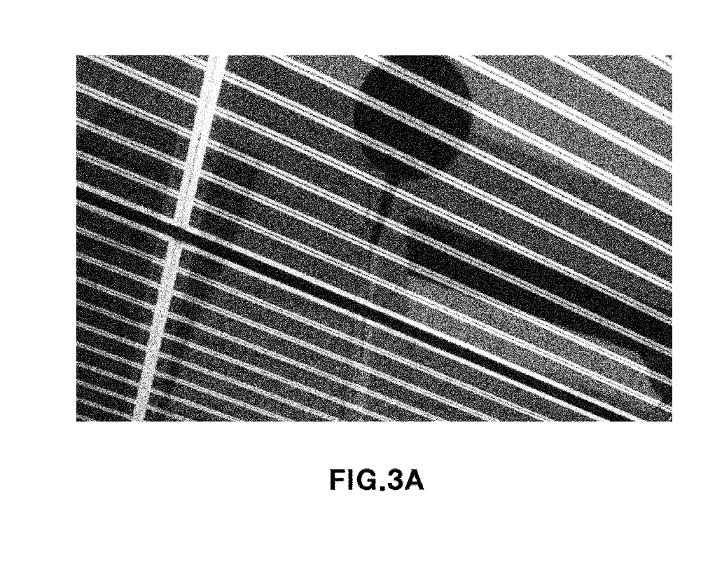

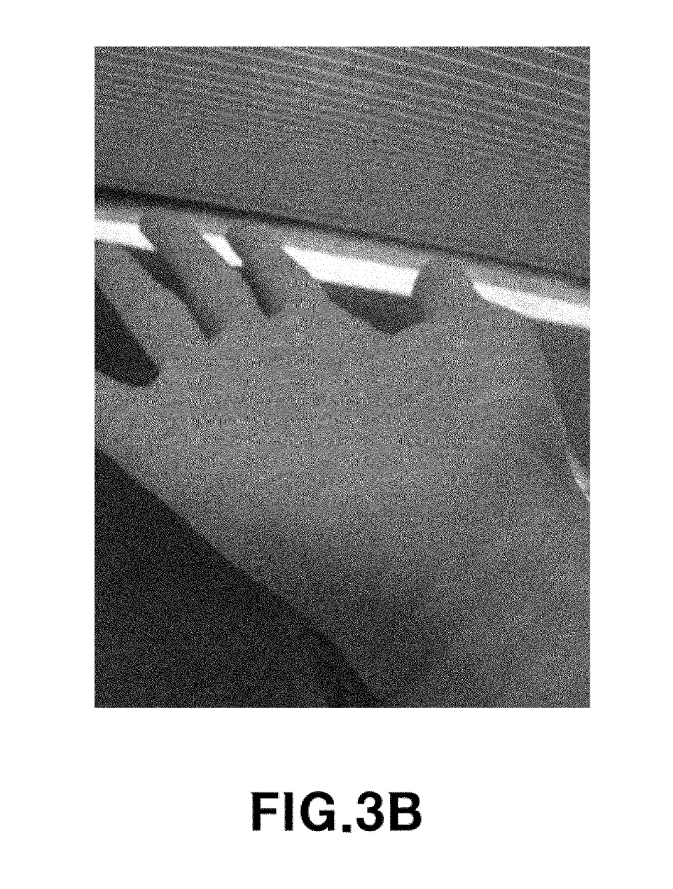

FIG. 3A is a picture showing a front surface of an amorphous solar cell having a scribing line, and FIG. 3B is a picture when shining a user's hand to the amorphous solar cell as a comparative example according to the present disclosure. FIG. 3A shows a semi-transparent amorphous solar cell having an active layer tuned with red color and scribing lines, and FIG. 3B shows dizziness being induced by using the scribing lines of the solar cell as an obstacle to user's view.

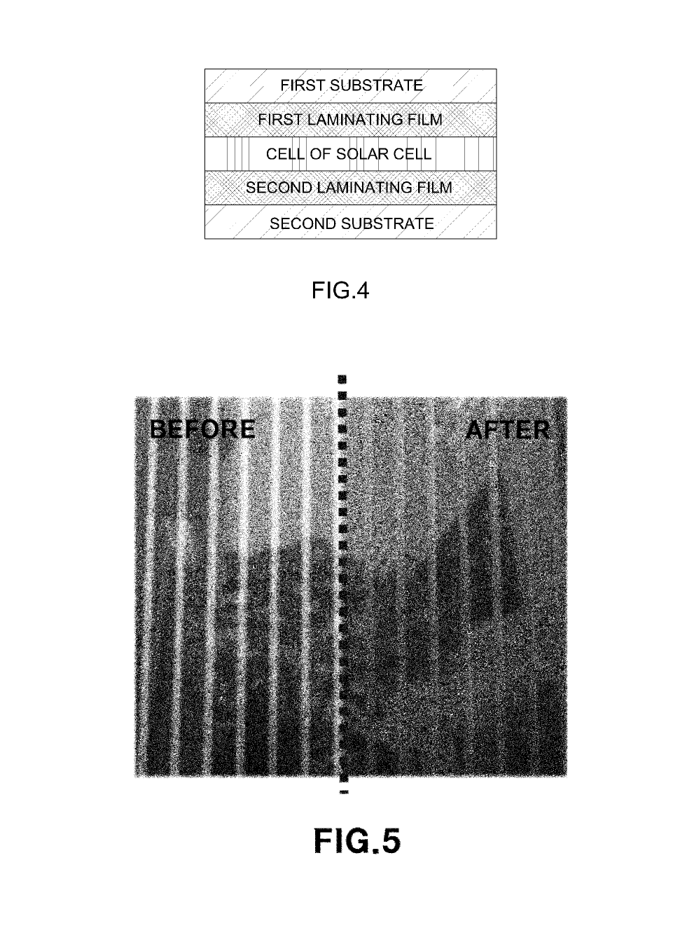

FIG. 4 is a cross-sectional diagram of the amorphous solar cell of Example 1 according to the present disclosure. In FIG. 4, a first substrate was glass, and first and the second laminating films were polyvinyl butyral (PVB). In the solar cell, scribing lines were repeatedly formed at regular spacing on an active layer having red color. In addition, the second substrate was pattern matched with the scribing line of the solar cell in which the pattern was tuned with red color as the active layer.

FIG. 5 is a picture showing a front surface of the amorphous solar cell of Example 1 according to the present disclosure before and after pattern matching the scribing line on the second substrate. Referring to FIG. 5, the repetitive pattern of the scribing lines are less noticeable due to a color difference of the red color after pattern matching on the second substrate while dizziness was induced 3 before pattern matching on the second substrate.

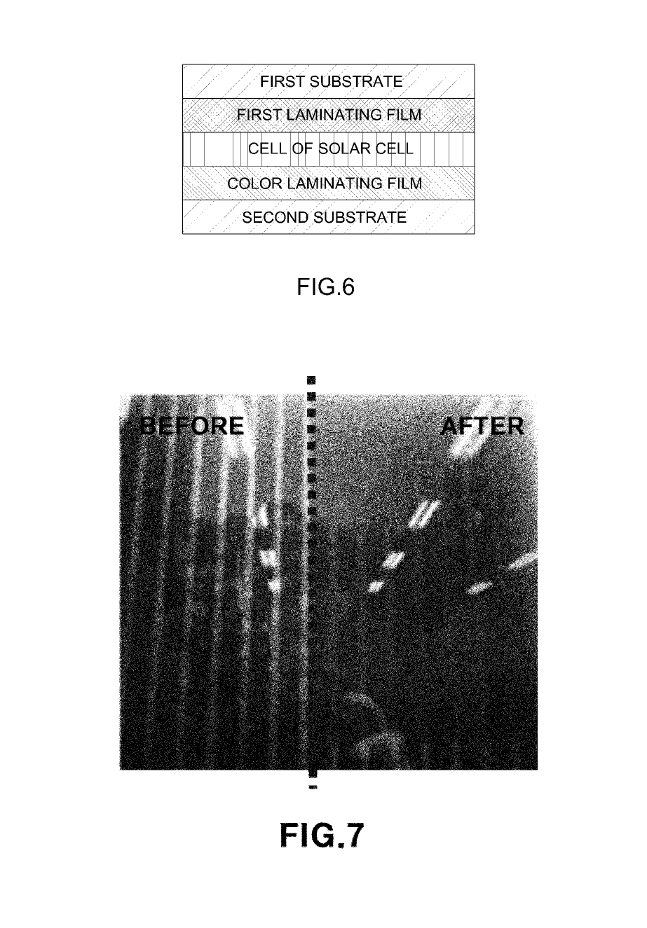

FIG. 6 is a cross-sectional diagram of an amorphous solar cell of Example 2 according to the present disclosure. In FIG. 6, the first substrate was glass, and the first laminating film was polyvinyl butyral (PVB). In the solar cell, the scribing lines were repeatedly formed at regular spacing on the active layer tuned with red color. The second laminating film was a color laminating film (polyvinyl butyral (PVB) mixed with red color), and the second substrate was pattern matched with the scribing line. Herein, the second substrate pattern was tuned with the same color as the active layer of the solar cell.

FIG. 7 is a picture showing a front surface of the amorphous solar cell of Example 2 according to the present disclosure before and after pattern matching the scribing line on a second substrate while the color laminating film is attached. As can be identified in FIG. 7, the overall color tone was partially corrected before forming a pattern on the second substrate while the color laminating film was attached as the second laminating film; however, dizziness caused by the scribing lines was still induced. After forming the pattern on the second substrate while the color laminating film was attached, the overall color tone was corrected, and at the same time, a color difference was reduced by RGB color adjustment between the active layer and the scribing lines, and dizziness induction was reduced since the repetitive pattern of the scribing line was less noticeable.

Accordingly, the amorphous solar cell according to Examples 1 and 2 enhances esthetic impression while preventing a moire phenomenon caused by the repetitive pattern of the scribing lines in the solar cell by pattern matching the scribing line on the second substrate and tuning the substrate with the same color as the active layer, and may mitigate dizziness induced by the color difference. In addition, visual fatigue may be improved by correcting the overall color tone of the solar cell by using a color laminating film, which is readily color-tuned, between the cell of the solar cell and the second substrate.

The solar cell according to the present disclosure enhances esthetic impression while preventing a moire phenomenon caused by repetition of a light absorption unit and a pattern unit in a solar cell and mitigates dizziness induced by a color difference by using a substrate tuned with the same color as the light absorption unit of the solar cell while pattern matching with the pattern unit.

In addition, visual fatigue may be improved by correcting the overall color tone of the solar cell by using a color laminating film, which is readily color-tuned, between the cell of a solar cell and the second substrate.

The invention has been described in detail with reference to exemplary embodiments thereof. However, it will be appreciated by those skilled in the art that changes may be made in these embodiments without departing from the principles and spirit of the invention, the scope of which is defined in the appended claims and their equivalents.

What is claimed is:

1. A packaging structure of a solar cell comprising:
a first substrate;
a first laminating film attached to a back surface of the first substrate;
the solar cell, which includes one or more substrates, attached to a back surface of the first laminating film and comprising a light absorption unit and a pattern unit;
a second laminating film attached to a back surface of the solar cell; and
a second substrate attached to a back surface of the second laminating film,
wherein the light absorption unit is color-tuned, and
the second substrate is tuned with the same color as the light absorption unit and pattern matched with the pattern unit.

2. The packaging structure of claim 1, wherein the first substrate is glass, a transparent plastic, or polymer film.

3. The packaging structure of claim 1, wherein the second substrate is glass, a transparent plastic, or polymer film.

4. The packaging structure of claim 1, wherein the first laminating film is polyvinyl butyral (PVB), ethylene vinyl acetate (EVA), or a mixture thereof.

5. The packaging structure of claim 1, wherein the second laminating film is polyvinyl butyral (PVB), ethylene vinyl acetate (EVA), or a mixture thereof.

6. The packaging structure of claim 3, wherein the second laminating film is a color laminating film.

7. The packaging structure of claim 1, wherein the light absorption unit is an active layer or a photoelectrode, and
the pattern unit is a scribing line or a collector electrode.

8. The packaging structure of claim 1, wherein the solar cell is an amorphous solar cell or a dye-sensitized solar cell.
